(19) United States
(12) Patent Application Publication
(10) Pub. No.: US 2019/0013402 A1
(43) Pub. Date: Jan. 10, 2019

(54) FIELD EFFECT SEMICONDUCTOR DEVICE WITH SILICON ALLOY REGION IN SILICON WELL AND METHOD FOR MAKING

(71) Applicant: GLOBALFOUNDRIES Inc., Grand Cayman (KY)

(72) Inventors: Jagar Singh, Clifton Park, NY (US); Shiv Kumar Mishra, Mechanicville, NY (US)

(21) Appl. No.: 15/642,675

(22) Filed: Jul. 6, 2017

(51) Int. Cl. H01L 29/78; H01L 29/40; H01L 29/66; H01L 29/06

(52) U.S. Cl. CPC H01L 29/7816; H01L 29/0615; H01L 29/66681; H01L 29/402

(57) ABSTRACT

A semiconductor device includes a substrate, a first well doped with dopants of a first conductivity type defined in the substrate, and a second well doped with dopants of a second conductivity type different than the first conductivity type defined in the substrate adjacent the first well to define a PN junction between the first and second wells. The second well includes a silicon alloy portion displaced from the PN junction. A source region is positioned in one of the first well or the second well. A drain region is positioned in the other of the first well or the second well. A gate structure is positioned above the substrate laterally positioned between the source region and the drain region.

### BACKGROUND OF THE INVENTION

### 1. Field of the Invention

The present disclosure relates to semiconductor devices and to a method of forming semiconductor devices, and, more particularly, to a field effect device with a silicon alloy region in a silicon well and methods for making same.

### 2. Description of the Related Art

In recent years, lateral double-diffused metal-oxide-semiconductor field effect transistors (LDMOSFETs) have been increasingly applied in high voltage and smart power applications. The advantages over vertical double-diffused MOSFETs (VDMOSFETs) are a reduction in the number of application steps, multiple output capability on the same chip, and compatibility with advanced very large scale integration (VLSI) technologies. LDMOSFETs with VLSI processes are expected to drive ICs to wider fields of complex applications, such as intelligent power ICs.

Generally, LDMOSFETs implement an asymmetric structure with a drift region located between the channel and drain contact of the LDMOSFET. In general, there is a correlation between the on-resistance (RON) and the breakdown voltage (BV) of the device based on the selected semiconductor materials. Materials that provide increased BV generally have higher values for RON, and vice versa. For example, if silicon germanium (SiGe) is employed, the increased hole mobility of SiGe compared to silicon reduces RON, but the BV is reduced.

The present disclosure is directed to various methods of forming an LDMOSFET with a silicon alloy region formed in a silicon well and the resulting device that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In accordance with a first aspect of the present invention, a semiconductor device is provided. In accordance with illustrative embodiments herein, the semiconductor device includes, among other things, a substrate, a first well doped with dopants of a first conductivity type defined in the substrate, and a second well doped with dopants of a second conductivity type different than the first conductivity type defined in the substrate adjacent the first well to define a PN junction between the first and second wells. The second well includes a silicon alloy portion displaced from the PN junction. A source region is positioned in one of the first well or the second well. A drain region is positioned in the other of the first well or the second well. A gate structure is positioned above the substrate laterally positioned between the source region and the drain region.

In a second aspect of the present disclosure, a semiconductor device includes, among other things, a silicon substrate, a first well doped with dopants of a first conductivity type defined in the silicon substrate, and a second well doped with dopants of a second conductivity type different than the first conductivity type defined in the silicon substrate adjacent the first well to define a PN junction between the first and second wells. The second well includes a silicon germanium portion having a material composition different than the silicon substrate and being displaced from the PN junction. A source region is positioned in one of the first well or the second well. A drain region is positioned in the other of the first well or the second well. A gate structure is positioned above the substrate laterally positioned between the source region and the drain region.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict various novel methods disclosed herein for forming a silicon alloy region in a silicon well and the resulting devices;

FIG. 2 illustrates a P-type LDMOSFET including the general structure of FIG. 1C; and

FIG. 3 illustrates an N-type LDMOSFET including the general structure of FIG. 1C.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless or otherwise indicated, all numbers expressing quantities, ratios and numerical properties of ingredients, reaction conditions and so forth used in the specification and claims are to be understood as being modified in all instances by the term “about.”

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

The person skilled in the art will appreciate that, although a semiconductor device may be provided by a MOS device, the expression “MOS” does not imply any limitation, i.e., a MOS device is not limited to a metal-oxide-semiconductor configuration, but may also comprise a semiconductor-oxide-semiconductor configuration and the like.

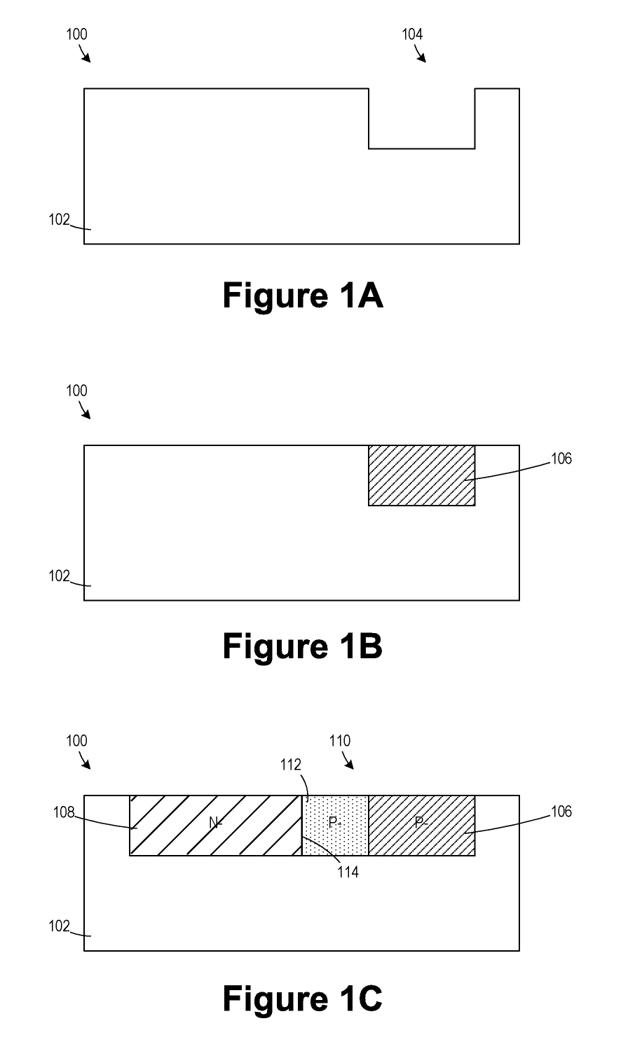

FIGS. 1A-1C schematically depict various illustrative embodiments of aspects of a novel lateral double-diffused metal-oxide-semiconductor (LDMOS) device 100 disclosed herein. In a general sense, in one broad aspect, the present disclosure is related to the formation of a novel field effect structure wherein a PN junction is formed between an N-well and a P-well formed in silicon regions. A silicon alloy region (e.g., silicon germanium—SiGe) is provided in the P-well laterally displaced from the PN junction. In some embodiments, other silicon alloys may be used, such as SiSn. The breakdown voltage of the device is governed by the silicon PN junction, but the on-resistance of the device is reduced by the silicon alloy region. Hence, increased breakdown voltage and decreased on-resistance may be achieved concurrently.

FIG. 1A illustrates the LDMOS device 100 at a very early stage of manufacture. An illustrative semiconducting substrate 102, such as a silicon substrate having a bulk or so-called silicon-on-insulator (SOI) configuration, is provided. Of course, the substrate 102 may be comprised of a variety of materials other than silicon, depending upon the particular application. The substrate 102 may be lightly pre-doped with dopants of a first conductivity type, such as P-type dopants (e.g., boron and the like), or may be undoped. A patterned etch process was performed to define a recess 104 in the substrate 102.

FIG. 1B illustrates the LDMOS device 100 after an epitaxial growth process was performed to define a silicon alloy region 106 in the recess 104. The silicon alloy region 106 may have a composition of SiₓAlloy₁₋ₓ, where x is generally less than 0.7. The silicon alloy region 106 may be doped in situ (e.g., with a P-type dopant) or it may be undoped.

FIG. 1C illustrates the LDMOS device 100 after a plurality of masked implantation processes were performed to define an N-well 108 (e.g., doped with an N-type dopant, such as phosphorus or arsenic) and a P-well 110 that includes a P-doped silicon region 112 and the silicon alloy region 106. In the general structure of FIG. 1C, a PN junction 114 is defined between the N-well 108 and the P-well 110. The breakdown voltage of the LDMOS device 100 is determined by the characteristics (e.g., material and doping) of the N-well 108 and the P-doped silicon region 112. In the illustrated embodiment, the N-well 108 and the P-doped silicon region 112 are both formed in silicon regions. The on-resistance of the LDMOS device 100 is affected by the characteristics of the P-doped silicon region 112 and the silicon alloy region 106. The presence of the silicon alloy region 106 reduces the on-resistance without sacrificing the higher breakdown voltage of silicon, as compared to the breakdown voltage of a silicon/silicon alloy PN junction. The general structure of the LDMOS device 100 of FIG. 1C may be adapted to a variety of semiconductor devices.

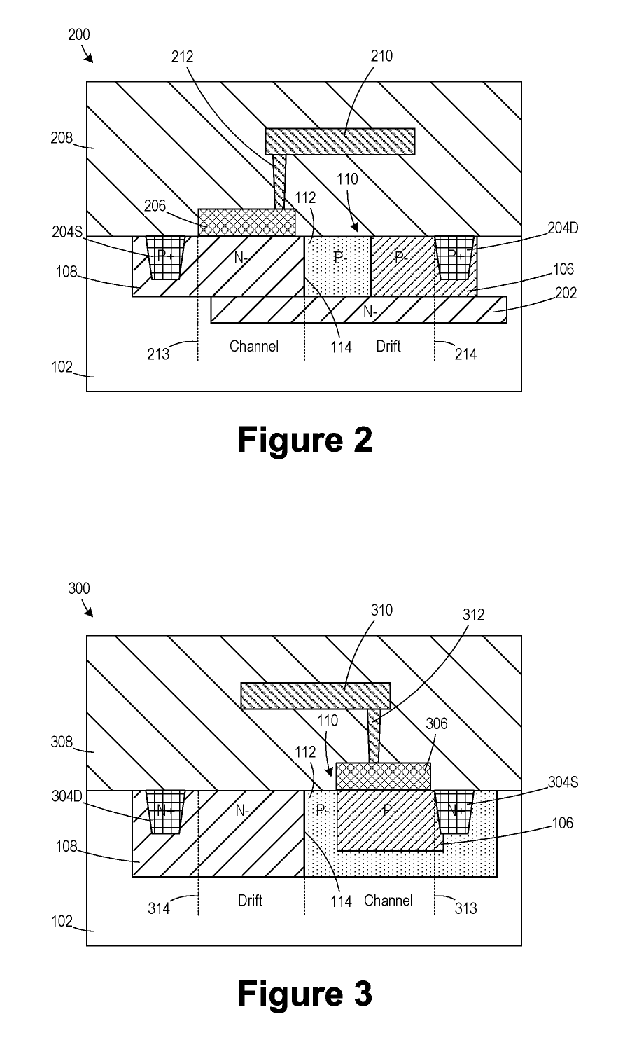

FIG. 2 illustrates a P-type LDMOSFET 200 including the general structure of FIG. 1C. One or more additional N-type implantations were performed to define a deep N-well 202 (N−). One or more additional P-type implantations were performed to define a P-type (P+) source region 204S in the N-well 108 and a P-type (P+) drain region 204D in the P-well 110. In some embodiments, the P-type drain region 204D may be embedded in the silicon alloy region 106. The shape of the P-type source/drain regions 204S, 204D in FIG. 2 is only meant as a general representation. The actual shape may be varied by performing multiple implantation steps with different mask profiles. A gate structure 206 (i.e., including a gate insulation layer (e.g., silicon dioxide, high-k dielectric, etc.) and a gate electrode (e.g., metal, polysilicon, work function adjusting material, barrier layer, etc.) (not separately shown) was formed above the N-well 108. The gate structure 206 may be formed using a gate first technique or a replacement gate technique. A dielectric layer 208 was formed above the gate structure 206. An optional field plate 210 including a via 212 contacting the gate structure 206 was formed in the dielectric layer 208.

The gate structure 206 is formed above a channel region 213 of the P-type LDMOSFET 200 defined in the N-well 108. The P-well 110 defines a drift region 214 between the drain regions 204D and the channel region 213. The drift region 214 of the P-type LDMOSFET 200 has a decreased resistance due to the higher hole mobility of the silicon alloy region 106. The breakdown voltage of the P-type LDMOSFET 200 is governed by the silicon material of the N-well 108 and the P-doped silicon region 112 at the PN junction 114.

FIG. 3 illustrates an N-type LDMOSFET 300 including the general structure of FIG. 1C. Note that the silicon alloy region 106 is embedded in the P-doped silicon region 112 of the P-well 110. The size and shape of the P-doped silicon region 112 may be determined by the masking process employed and the implantation energy selected. One or more additional P-type implantations were performed to define an N-type (N+) source region 304S in the P-well 110 and an N-type (N+) drain region 304D in the N-well 108. In some embodiments, the N-type drain region 204D may be embedded in the P-doped silicon region 112 interfacing with an edge of the silicon alloy region 106. Alternatively, the N-type drain region 204D may be partially embedded in both the P-doped silicon region 112 and the silicon alloy region 106. The shape of the N-type source/drain regions 304S, 304D in FIG. 3 is only meant as a general representation. The actual shape may be varied by performing multiple implantation steps with different mask profiles. A gate structure 306 (i.e., including a gate insulation layer (e.g., silicon dioxide, high-k dielectric, etc.) and a gate electrode (e.g., metal, polysilicon, work function adjusting material, barrier layer, etc.) (not separately shown) was formed above the P-well 110. In some embodiments, the gate structure 306 is formed above the silicon alloy region 106. The gate structure 306 may be formed using a gate first technique or a replacement gate technique. A dielectric layer 308 was formed above the gate structure 306. An optional field plate 310 including a via 312 contacting the gate structure 306 was formed in the dielectric layer 308.

The gate structure 306 is formed above a channel region 313 of the P-type LDMOSFET 200. The N-well 108 defines a drift region 314 between the drain region 304D and the channel region 313. The channel region 313 of the N-type LDMOSFET 300 has a decreased resistance due to the higher hole mobility of the silicon alloy region 106. The breakdown voltage of the N-type LDMOSFET 300 is governed by the silicon material of the N-well 108 and the P-doped silicon region 112 at the PN junction 114.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A semiconductor device, comprising:
a substrate;
a first well doped with dopants of a first conductivity type defined in said substrate;
a second well doped with dopants of a second conductivity type different than said first conductivity type defined in said substrate adjacent said first well to define a PN junction between said first and second wells, wherein said second well includes a silicon alloy portion displaced from said PN junction, wherein said silicon alloy portion does not contact said PN junction and said silicon alloy portion is doped with dopants of said second conductivity type;
a source region positioned in one of said first well or said second well;
a drain region positioned in the other of said first well or said second well; and
a gate structure positioned above said substrate laterally positioned between said source region and said drain region.

2. The semiconductor device of claim 1, wherein said source and drain regions are doped with dopants of said second conductivity type, and said gate structure is positioned above said first well without overlapping said PN junction.

3. The semiconductor device of claim 2, wherein said drain region is embedded in said silicon alloy portion.

4. The semiconductor device of claim 3, wherein said second well defines a drift region between said drain region and said first well.

5. The semiconductor device of claim 4, further comprising a field plate embedded in a dielectric layer positioned above said gate structure, wherein said field plate is positioned laterally above at least a portion of said drift region and coupled to said gate structure.

6. The semiconductor device of claim 2, wherein a portion of said second well not including said silicon alloy region has a depth equal to that of said silicon alloy region.

7. The semiconductor device of claim 2, further comprising a deep implant region including dopants of said first type positioned below said second well.

8. The semiconductor device of claim 1, wherein said source and drain regions are doped with dopants of said first conductivity type, and said gate structure is positioned above said second well without overlapping said PN junction.

9. The semiconductor device of claim 8, wherein said drain region is embedded in said first well.

10. The semiconductor device of claim 9, wherein said first well defines a drift region between said drain region and said second well.

11. The semiconductor device of claim 10, further comprising a field plate embedded in a dielectric layer positioned above said gate structure, wherein said field plate is positioned laterally above at least a portion of said drift region and coupled to said gate structure.

12. The semiconductor device of claim 8, wherein said silicon alloy portion is embedded in a portion of said second well not including said silicon alloy region and has a depth greater than that of said silicon alloy region.

13. The semiconductor device of claim 12, wherein said source region is embedded in said portion of said second well not including said silicon alloy region and at least an edge region of said silicon alloy region.

14. The semiconductor device of claim 1, wherein a base material of said first well and said portion of said second well not including said silicon alloy region is silicon.

15. The semiconductor device of claim 14, wherein said silicon alloy region comprises silicon germanium and said base material does not include germanium.

16. A semiconductor device, comprising:
a silicon substrate;
a first well doped with dopants of a first conductivity type defined in said silicon substrate;
a second well doped with dopants of a second conductivity type different than said first conductivity type defined in said silicon substrate adjacent said first well to define a PN junction between said first and second wells, wherein said second well includes a silicon germanium portion having a material composition different than said silicon substrate and being displaced from said PN junction, wherein said silicon germanium portion does not contact said PN junction and said silicon germanium portion is doped with dopants of said second conductivity type;
a source region positioned in one of said first well or said second well;
a drain region positioned in the other of said first well or said second well; and
a gate structure positioned above said substrate laterally positioned between said source region and said drain region.

17. The semiconductor device of claim 16, wherein said source and drain regions are doped with dopants of said second conductivity type, said gate structure is positioned above said first well without overlapping said PN junction, and said drain region is embedded in said silicon germanium portion.

18. The semiconductor device of claim 17, wherein said second well defines a drift region between said drain region and said first well.

19. The semiconductor device of claim 16, wherein said source and drain regions are doped with dopants of said first conductivity type, said gate structure is positioned above said second well without overlapping said PN junction, and said drain region is embedded in said first well.

20. The semiconductor device of claim 19, wherein said first well defines a drift region between said drain region and said second well.
